(19) United States
(12) Patent Application Publication
(10) Pub. No.: US 2006/0240761 A1
(43) Pub. Date: Oct. 26, 2006

(54) Duct system and receiving device

(76) Inventor: Shoichi Yamaguchi, Nagano (JP)

Correspondence Address: BLANK ROME LLP, 600 NEW HAMPSHIRE AVENUE, N.W., WASHINGTON, DC, 20037, US

(21) Appl. No.: 10/534,020

(22) PCT Filed: Jun. 25, 2004
(86) PCT No.: PCT/JP04/09024

§ 371 Date: Jun. 13, 2006

(30) Foreign Application Priority Data
Jun. 27, 2003 (JP) 2003-185428

(51) Int. Cl. H05K 5/00

(52) U.S. Cl. 454/184

(57) ABSTRACT

A duct system includes a first duct that guides hot air downward from a hot air generator disposed thereabove and includes a plurality of hot air supply openings at intermediate positions thereof, a second duct that guides cold air upward from a cold air generator disposed therebelow and includes a plurality of cold air supply openings at intermediate positions thereof, and a third duct that connects the hot air generator and the cold air generator and includes a plurality of return openings at intermediate positions thereof. Using this duct system, it is possible to provide a simple duct system that can supply cold air and hot air independently and can return air in a shared duct. Accordingly, it is possible to provide a storage apparatus, such as a showcase, that is compact and has high heat exchanging efficiency.

### TECHNICAL FIELD

The present invention relates to a storage apparatus such as a showcase that can heat and/or chill products at different temperature conditions in a supermarket, a convenience store, or the like.

### BACKGROUND ART

As one example of a showcase that is set up in a supermarket or the like to show or display products (commercial products), there is known a showcase called an “open showcase” where an air curtain is formed at the front surface of a case so that products such as canned drinks can be chilled. In a showcase disclosed by Japanese Laid-Open Patent Publication No.S55-165468 (hereinafter S55-165468), cold air is blown out downwards from the front ends of shelves, with the cold air that has been blown out from upper shelves being sucked in from the front ends of lower shelves so that individual air curtains are formed in each space that is partitioned by the shelves, thereby maintaining an environment suited to chilling the inside of the case.

When many types of products are displayed or shown in a showcase, there are cases where environmental conditions such as temperature should be changed for each type of products. In a showcase shown in prior art in the S55-165468 that is covered with a single air curtain, the upper shelves that are close to the cold air blow openings are well chilled but the lower shelves are difficult to chill. It is therefore preferable to place products for which chilling is desired on the upper shelves and products for which chilling is not desired on the lower shelves. However, since the difference in temperature is merely one of the upper shelves being well chilled and the lower shelves being difficult to chill, it is not possible to actively control the temperature.

The technology disclosed in the S55-165468 eradicates the difference in temperature in that the upper shelves are well chilled and the lower shelves are difficult to chill by blowing out cold air downward from the front ends of the upper shelves and sucking in the cold air from the front ends of the lower shelves, thereby making the distances covered by the air curtains shorter. Accordingly, the temperature inside the showcase becomes constant, and various types of products cannot be stored at different temperatures.

### DISCLOSURE OF THE INVENTION

To form different temperature regions inside a showcase, a method where ducts that supply cold air and ducts that supply hot air are provided and cold air and hot air are respectively supplied can be proposed. However, with this method, there is the problem that double the number of supply ducts are required and double the number of the return ducts are also required. A method that chills air returned from the chilled regions for cold air and heats air returned from the heated regions for hot air has higher thermal efficiency than methods that chills the external air and heats the external air. However, when a chilled region where cold air is blown out and a heated region where hot air is blown out are provided inside the same showcase, if a return duct is shared between the chilled region and the heated region, the cold air and hot air will be mixed inside the duct, resulting in conditions that do not differ to the case where the external air is chilled or heated. It is one of idea that, when both a chilled region and a heated region are formed inside a showcase, return ducts are not required.

However, when a showcase is used for only chilling or only heating, the thermal efficiency is improved by returning the cold air or the hot air, resulting in a large reduction in running cost, so that return ducts cannot be omitted. A duct system for separately returning the cold air and the hot air is therefore required. Accordingly, when supplying cold air and hot air to produce chilled and heated regions inside a showcase, the amount of ducting is instantly doubled, the size of the showcase is increased, and the manufacturing cost is also increased.

It is an object of the present invention to provide a simple duct system that can independently supply and return cold air and hot air. It is a further object of the present invention to provide a storage apparatus that includes such duct system, is compact, has high heat exchanging efficiency, and enables a heated region and chilled region to be simultaneously produced within the storage region.

In the present invention, a duct that guides hot air downward from a hot air generator disposed thereabove, a duct that guides cold air upward from a cold air generator disposed therebelow, and a shared return duct that connects the hot air generator and the cold air generator are provided. Inside the return duct, high-temperature air is returned upward to the hot air generator and low-temperature air is returned downward to the cold air generator due to the difference in specific gravity. That is, a duct system according to the present invention comprises a first duct that guides hot air downward from a hot air generator disposed thereabove and includes a plurality of hot air supply openings at intermediate positions thereof, a second duct that guides cold air upward from a cold air generator disposed therebelow and includes a plurality of cold air supply openings at intermediate positions thereof, and a third duct that connects the hot air generator and the cold air generator and includes a plurality of return openings at intermediate positions thereof.

In the duct system according to the present invention, the third duct is a shared discharge and return duct for the hot air and the cold air, with the hot air generator being above the third duct and the cold air generator being below the third duct. Accordingly, the high-temperature air and low-temperature air returned inside the third duct can be respectively returned to the hot air generator and the cold air generator without mixing. That is, out of the high-temperature air and the low-temperature air returned inside the third duct, the difference in specific gravity results in the high-temperature air being returned to the hot air generator located up-side by an updraft and the low-temperature air being returned to the cold air generator located down-side by a downdraft. In addition, when a heated region and a chilled region are formed in the storage space, in view of the specific gravity of the air, the heated region is positioned above the chilled region and high-temperature air is returned at a higher part of the third duct than the low-temperature air. Accordingly, even if a shared third duct is provided for discharging, the high-temperature air and the low-temperature air can be returned separately so that the heat exchanging efficiency of the hot air generator and the cold air generator can be improved compared to a case where external air is heated and chilled or a case where a mixture of the high-temperature air and the low-temperature air is heated or is chilled. This means that it is possible to provide a highly efficient duct system that has a simple construction.

In the duct system of the present invention, the direction in which the air is returned is determined automatically according to the temperature of the air returned in the third duct. Accordingly, the duct system of the present invention is not limited to a storage apparatus in which a heated compartment and a chilled compartment are formed by supplying only hot air or only cold air, and it is also possible to apply the duct system to a storage apparatus in which a compartment with an appropriate temperature is formed by mixing the hot air and the cold air. The heat exchanging efficiency falls if air that is colder than room temperature is recovered to the hot air generator and the heat exchanging efficiency also falls if air that is warmer than room temperature is recovered to the cold air generator. For this reason, in the present specification, the expression “hot air” refers to an air flow that is warmer than room temperature and “cold air” refers to an air flow that is colder than room temperature.

Using the duct system of the present invention a storage apparatus is provided, the storage apparatus includes a first duct, a second duct, a third duct, a hot air generator, a cold air generator, and a housing that constructs a storage space to which at least one of hot air and cold air is supplied by at least one of the first duct and the second duct and from which internal air is returned by the third duct. The storage apparatus can provide a plurality of temperature regions in the storage space with a small duct space and a compact overall size. In addition, from the storage space, the low-temperature return air is supplied to the cold air generator and the high-temperature return air is supplied to the hot air generator. Accordingly, the heat exchanging efficiency of the cold air generator and the hot air generator is high, so that the heat exchanger for chilling and the heater used for heating can be made smaller, thereby making it possible to provide an even more compact storage apparatus. By applying the duct system of the present invention to a storage apparatus where display shelves on which products are displayed are connected to hot air supply openings and/or cold air supply openings, it is possible to provide a compact storage apparatus with high heat exchanging efficiency.

For the duct system and storage apparatus according to the present invention, in one preferred aspect, a shared supply duct that connects the supply side of a hot air generator and the supply side of a cold air generator is provided, and the first duct and the second duct are produced by dividing the shared supply duct using a partitioning means such as a damper or a partitioning plate. By dividing a single shared supply duct into the first and second ducts, the number of ducts can be reduced, so that the constructions of the duct system and the storage apparatus can be simplified and made more compact. In the case where the shared supply duct is used, the hot air generator and the cold air generator should preferably be provided with backflow preventing mechanisms that block air flows in a reverse direction. By doing so, by merely removing the partitioning means of the shared supply duct and operating only one of the hot air generator and the cold air generator, it is possible to supply only hot air or cold air to the storage space to heat or chill the entire space.

In the case where only hot air or cold air is supplied, the air flow that pass the respective counter generator is reversed, so that by providing the backflow preventing mechanisms, it is possible to prevent the hot air generator and the cold air generator acting as ducts that short the shared supply duct and the third duct. The backflow preventing mechanisms can be provided at output, input, or intermediate positions of the generators, and it is possible to use mechanisms that close a damper manually or electrically, or using differential pressure.

Supplying hot air, cold air, or air mixed of the hot air and cold air with appropriate proportions via a display shelf for displaying products is effective in providing a storage apparatus where products arranged above or below the display shelf are kept at an appropriate temperature. That is, the present invention provides a storage apparatus that includes, in addition to the ducts of the duct system described above, a display shelf that is connected to at least one of the cold air supply openings and the hot air supply openings and includes blow openings that blow out at least one of hot air and cold air via the display shelf itself. The display shelf may also include suction holes, and by connecting the display shelf to the return openings, air can be discharged via the display shelf.

### BRIEF DESCRIPTION OF THE DRAWINGS

FIG. 1 is a vertical cross-sectional view schematically showing a storage apparatus according to the present invention.

FIG. 2 is a perspective view that schematically shows the interior of a case of the storage apparatus shown in FIG. 1, when seen through a housing.

FIG. 3 is a planar diagram showing the duct system of the storage apparatus.

FIG. 4 is a perspective view showing the appearance of a display shelf.

FIG. 5 is a series of cross-sectional views showing the construction of a display shelf, with FIG. 5A being a cross-sectional view of a part including a hot air inflow opening, FIG. 5B being a cross-sectional view of a part including a cold air supply opening, and FIG. 5C being a cross-sectional view of a part including a return opening.

FIG. 6 is a perspective view showing the appearance of a display shelf that blows out hot air from an upper surface thereof and blows out cold air from a rear surface thereof.

FIG. 7 is a perspective view schematically showing the interior of the case of a different storage apparatus, in a state where a display shelf has been removed.

FIG. 8 is a planar diagram showing a duct system of the storage apparatus shown in FIG. 7.

FIG. 9 is a diagram showing a damper that opens and closes a duct due to differential pressure in the duct.

FIG. 10 is a diagram showing a state where a plurality of dampers are provided inside the supply duct.

FIG. 11 is a diagram showing the open/closed states of various types of dampers in accordance with operating modes.

### BEST MODE FOR CARRYING OUT THE INVENTION

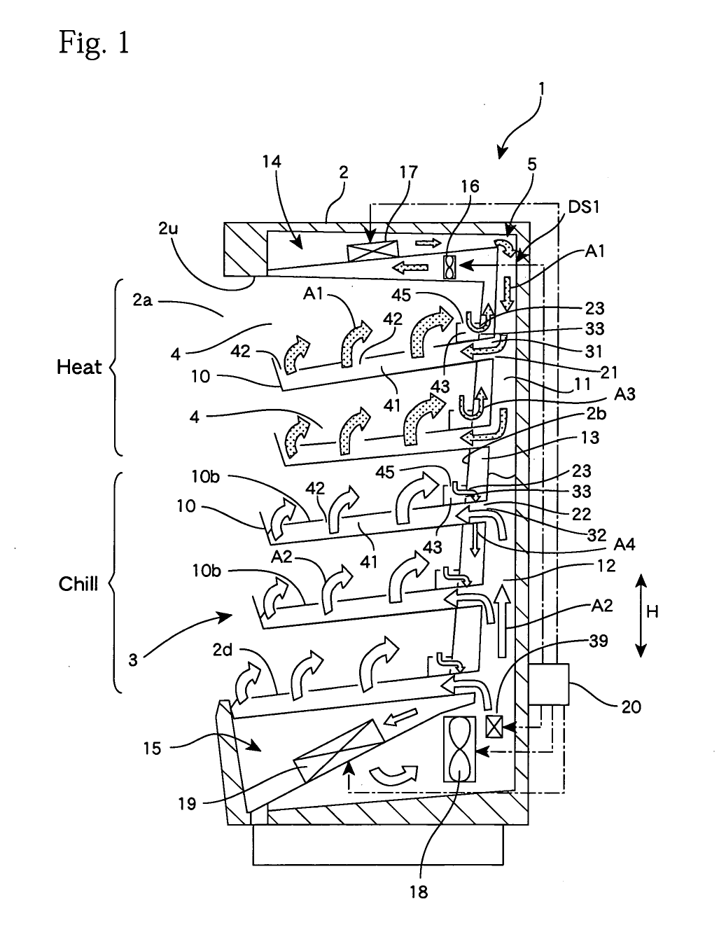

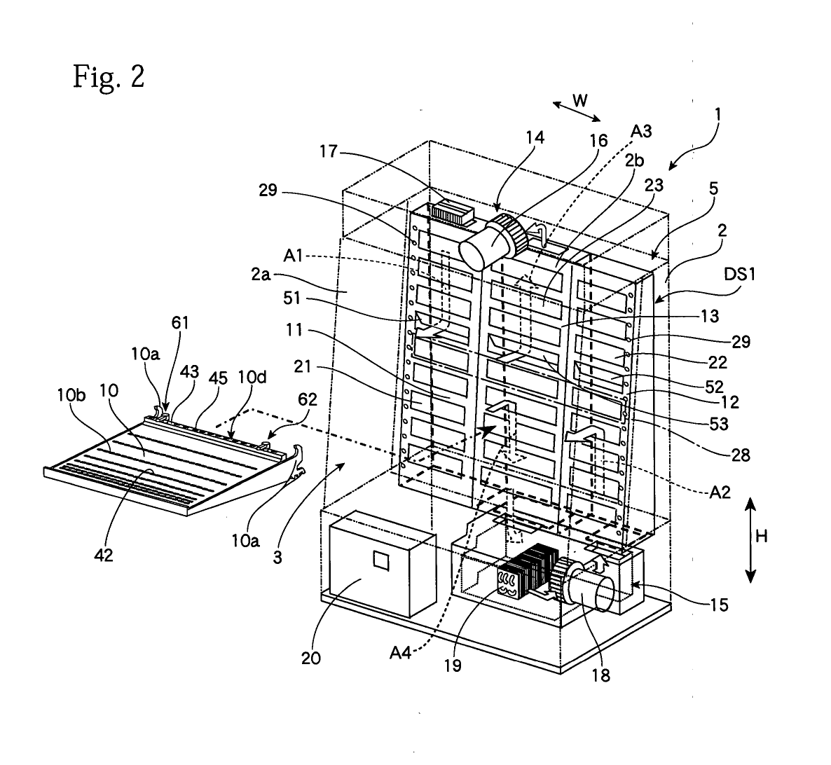

The present invention is described in more detail below with reference to the drawings. FIG. 1 is a cross-sectional view schematically showing the construction of a storage apparatus of the present invention. FIG. 2 is a perspective view that schematically shows the internal construction of the storage apparatus 1 when seen through a housing 2. The housing 2 shown in FIG. 2 constructs a storage space and is shown in a state where display shelves have been removed. The storage apparatus 1 includes the insulated housing 2, with the housing 2 forming a display case. The interior of the housing 2 is a storage space 3 in which display shelves 10 are disposed. A plurality of display shelves 10 can be disposed in the storage space 3 at appropriate intervals in an up-down direction, with such display shelves 10 partitioning the storage space 3 in the up-down direction. The respective zones in a plurality of zones 4 partitioned by the display shelves 10 can be thought of as units for supplying and/or discharging air, which is required to maintain the quality and the like of products, to products (commercial products) that are displayed on the display shelves 10.

In the state shown in FIG. 1, the storage space 3 is compartmentalized by four display shelves 10 arranged vertically to form five zones 4 in the up-down direction. The uppermost zone 4 is the space between the roof 2u of the display case 2 and a shelf 10, while the second to fourth zones 4 from the top are spaces with shelves 10 above and below and the lowermost zone 4 is the space between a shelf 10 and a base 2d of the display case 2. In this storage apparatus 1, air for environmental conditioning such as chilling or heating is supplied via the display shelves 10, circulates inside the zones 4 and is sucked in and discharged via the display shelves 10. Accordingly, independent air cycles can be formed on a display shelf basis. This means that environmental conditions including temperature, humidity, and the like can be set and maintained on a display shelf basis for the products displayed on the display shelves 10. Although the storage apparatus 1 is an open showcase where the front surface 2a of the display case 2 is open, the internal storage space 3 is divided into a plurality of spaces where different conditions can be set.

The interior of a rear wall 2b that forms the rear surface of the housing 2 is a duct space 5 in which a duct system DS1 according to the present invention is housed. The duct system DS1 includes a hot air supply duct (first duct) 11, a cold air supply duct (second duct) 12, and a discharge duct (third duct) 13 that are extended in the up-down direction H and disposed in parallel. Although the supply ducts 11, 12 and the discharge duct 13 have been illustrated in FIG. 1 as being aligned in the front-back direction to clearly show the individual ducts, as shown in FIG. 2, the ducts should preferably be aligned in the width or left-right direction W. By aligning the ducts in the width direction, the thickness of the duct space 5 in the front-back direction can be reduced.

Equipment spaces 14 and 15 are formed in the roof 2u and the base 2d of the housing 2 of the storage apparatus 1. The equipment space 14 of the roof 2u is a hot air generator that generates high-temperature conditioning air A1, with a heater 17 for heating and a circulating fan 16 being disposed therein. The hot air generator 14 heats air sucked in from the storage space 3 via the discharge duct 13 and supplies the hot air (warm air) A1 to the storage space 3 via the hot air supply duct 11 from above. The equipment space 15 of the base 2d is a cold air generator that generates low-temperature conditioning air A2, with a heat exchanger 19 for chilling and a circulating fan 18 being disposed therein. The cold air generator 15 chills air sucked in from the storage space 3 via the discharge duct 13 and supplies the cold air A2 to the storage space 3 via the cold air supply duct 12 from below. In addition, a humidifier 39 is disposed in the cold air equipment space 15, so that the humidity can also be adjusted. The equipment of the hot air generator 14 and the equipment of the cold air generator 15 are controlled by a control apparatus 20, and hot air A1 and cold air A2 for environmental conditioning that have been controlled so as to be predetermined temperatures are supplied from the respective generators 14 and 15 to the respective supply ducts 11 and 12.

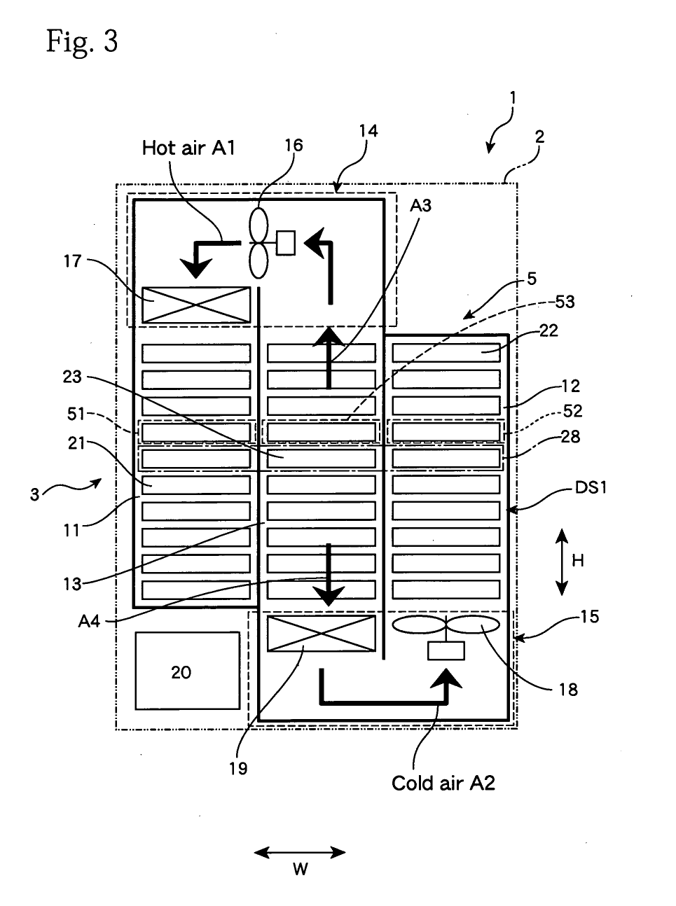

FIG. 3 shows the duct system DS1. In the hot air supply duct 11, a plurality of hot air supply openings 21 are formed with an appropriate pitch in the up-down direction. The openings 21 are connections for the respective display shelves 10 and the hot air A1 is supplied via the display shelves 10. In the cold air duct 12, a plurality of cold air supply openings (connection openings) 22 are also formed with an appropriate pitch. The openings 22 are connections for the respective display shelves 10 and the cold air A2 is supplied via the display shelves 10. In the discharge duct 13, a plurality of return openings 23 are formed with an appropriate pitch in the up-down direction. The openings 23 are connections for the respective display shelves 10 and air is discharged via the display shelves 10. These supply openings 21, 22 and return openings 23 are designed so as to be linearly aligned in a horizontal direction for the rear surface 2b of the housing 2, that is, the left-right direction W when looking from the front surface 2a of the housing 2. By such arrangement, connection regions 28, in each of which a supply opening 21, a supply opening 22 and a return opening 23 are aligned in the left-right direction, are disposed at fixed intervals in the up-down direction on the rear surface 2b of the case.

In the storage apparatus 1, by attaching a shelf 10 to any of the connection regions 28, one of the hot air A1 and the cold air A2, or a mixed air of the two according to desired conditions can be supplied via the shelf 10, with it also being possible to discharge air from the zone 4. Dampers 51, 52, and 53 are disposed on the respective connection openings 21, 22 and the return openings 23, with such dampers 51, 52, 53 being closed when a shelf 10 is not attached. In FIG. 3, the mounting of the dampers 51, 52, and 53 respectively disposed on the supply openings 21, 22 and the return opening 23 included in one connection region 28 is shown using broken lines. Dampers are also respectively provided on the supply openings 21, 22 and the return openings 23 included in the other connection regions 28, however, such dampers are not shown in the figure.

As shown in FIG. 2, the respective display shelves 10 can be detachably attached to freely chosen connection regions 28 by having hooks 10a that protrude from the rear surfaces of the shelves 10 engage attachment holes 29 that are provided in the rear surface 2b of the case 2.

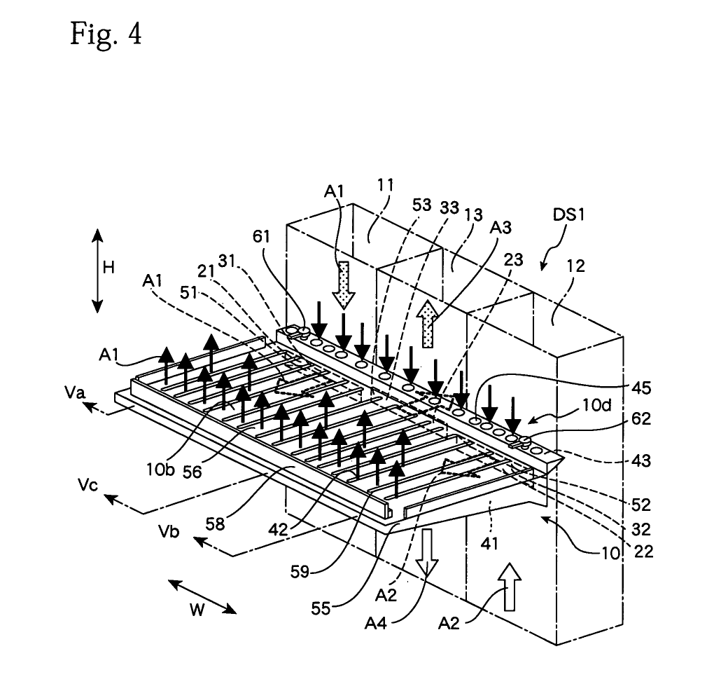

FIG. 4 is a perspective view showing the outline of a display shelf 10 and the direction of the air that flows in the ducts 11 to 13. On the rear surface 10d of each display shelf 10 that is attached to the rear surface 2b of the housing 2, intake openings 31, 32 and an outlet opening 33 are formed in a line in the left-right direction W. The intake openings 31, 32 and an outlet opening 33 are respectively connected to the openings 21 and 22 formed in the supply ducts 11 and 12 and the opining 23 formed in the return duct 13. A shelf supply duct 41 that is connected to the intake openings 31 and 32 is formed on the interior of each display shelf 10, with the shelf supply duct 41 being connected to a plurality of blow openings 42 distributed on a surface 10b of the display shelf 10. Accordingly, the hot air A1 supplied from the intake opening 31 and/or the cold air A2 supplied from the intake opening 32 are blown out via the display shelf 10 onto the products. The plurality of blow openings 42 are formed in the shelf surface 10b on which products are aligned, so that when products are displayed on the shelf 10, the products will be disposed above the blow openings 42 and the flow of the hot air A1 or the cold air A2 blown out from the shelves 10 will efficiently contact the products. The blow openings 42 may be holes or may alternatively be slits.

In addition, a shelf discharge duct 43 with suction openings 45 for sucking in and exhausting air from a zone 4 is disposed on a base side 10d of a display shelf 10. The display shelves 10 each include internal duct system including the supply duct 41 and the discharge duct 43. The suction openings 45 are connected to the outlet opening 33. The air sucked in from the suction openings 45 is returned to the return duct 13 via the discharge duct 43 of the shelf 10.

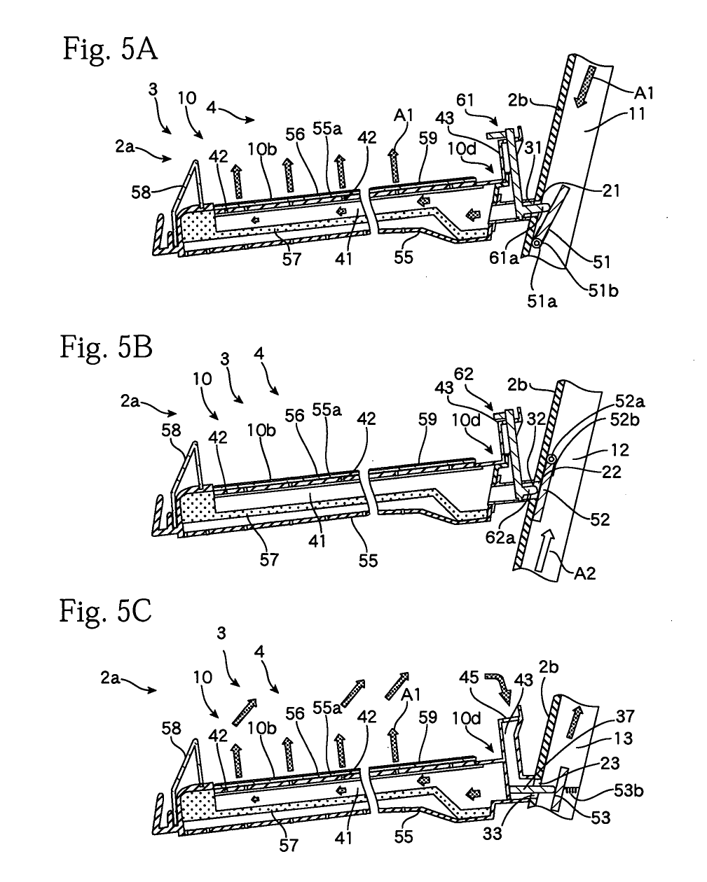

FIG. 5 includes three cross-sectional views of the internal construction of a display shelf 10. FIG. 5A is a cross-sectional view of the left side of a shelf 10 when viewed from the front 2a of the case 2 (unless noted otherwise in the present specification, the direction looking from the front surface 2a is shown), with the hot air intake opening 31 positioned on the left side of the base end 10d being visible. FIG. 5B is a cross-sectional view of the right side of a shelf 10, with the cold air intake opening 32 positioned on the right side of the base end 10d being visible. FIG. 5C is a cross-sectional view of a substantially central part of a shelf 10, with the return opening 33 positioned in substantially the center of the base end 10d being visible.

The display shelf 10 includes a shelf main body 55 that is concave, and a shelf plate 56 that closes an opening 55a in the shelf main body 55. The space surrounded by the shelf main body 55 and the shelf plate 56 is a space for the internal supply duct 41. Insulation material 57 for preventing condensation is disposed in this space to divide the space into upper and lower spaces. The upper space divided by the insulation material 57, that is, the space between the insulation material 57 and the shelf plate 56 is the shelf supply duct 41. The plurality of blow openings 42 are formed in the shelf plate 56 and the air A mixed in the shelf supply duct 41 is supplied from the plurality of blow openings 42 in the shelf plate 56 to the products. Accordingly, air set at desired conditions is blown out of the display shelf 10 so as to contact the products disposed on the shelf 10 immediately after being blown out, so that the air efficiently contacts the products disposed on the display shelf 10 and the environmental conditions thereof are maintained. A lattice or lattice-like plate 59 made of resin is placed on the shelf plate 56. By using a fluororesin with a low friction coefficient or the like as the lattice-like plate 59, it is possible to facilitate the sliding of canned drinks and the like on the display shelf 10. In addition, the lattice 59 functions so as to provide a certain amount of distance between products such as canned drinks and the blow openings 42 so that the supplying of the air is not blocked by the products. A toppling preventing plate 58 is provided at the front of the shelf main body 55.

In the example shown in FIG. 5, hot air A1 is taken in and blown out of the display shelves 10. Therefore, as shown in FIG. 5A, the supply opening 21 for hot air A1 is opened. A damper opening control lever 61 on the left of the shelf 10 is operated and an operation pin 61a is set to protrude rearward toward the connection opening 21. The pin 61a presses the damper 51 to open the connection opening 21 and supply hot air. The damper 51 is supported so that a lower end 51a is able to rotate, and is pressed by a spring 51b attached to the end 51a in a direction that closes the connection opening 21. The damper 51 is normally closed and, but when the operation pin 61a is protrude rearward from the shelf 10 by operation of the knob 61, the damper 51 rotates and opens the connection opening 21. The damper 51 opens upward, so that the supplying of the hot air A1 that is supplied from above to below in the duct 11 to the display shelves 10 is facilitated.

On the other hand, as shown in FIG. 5B, the supply opening 22 for the cold air A2 is closed. The operation pin 62a dose not protrude into the supply opening 22 with the operation of the damper opening control knob 62 on the right of the shelf 10, so that the damper 52 does not open, the supply opening 22 remains closed, and the cold air A2 is not supplied to the shelf 10. Accordingly, only the hot air A1 is outputted from the shelf 10. Note that the damper 52 is supported so as to be able to rotate about an upper end 52a thereof and is pressed onto the connection opening 22 by a spring 52b. Accordingly, if the operation pin 62a protrudes rearward, the damper 52 opens downward and the supplying of the cold air A2 that is supplied from below to above in the duct 12 to the display shelves 10 is facilitated.

With these damper control knobs 61 and 62, it is possible to open one of the dampers and close the other damper so that only hot air A1 is supplied to the zone compartmentalized by the shelf 10 to heat products or only cold air A2 is supplied to chill products. Alternatively both the hot air A1 and the cold air A2 can be mixed inside the shelf 10 and blown out so that products can be stored at an intermediate temperature.

The damper 53 provided on the return opening 23 of the return duct 13 slides to the front and rear and is pressed by a spring 53b in a direction so as to close the return opening 23. Accordingly, when a display shelf 10 is attached, the damper 53 is pressed by an operation pin 37 that protrudes to the rear from the shelf 10 so that the shelf discharge duct 43 of the shelf 10 is connected to the return duct 13 of the housing 2.

Accordingly, as shown in FIG. 4, in the storage apparatus 1 of the present embodiment, by attaching the shelf 10, a system is constructed where the hot air A1 supplied from above by the hot air supply duct 11, the cold air A2 supplied from below by the cold air supply duct 12, or a mixture of such air is supplied to products via the shelves 10, with air also being recovered by the return duct 13 via the shelves 10. This means that by simply attaching a shelf 10, it is possible to blow out air of a desired temperature and keep products in the desired environmental conditions. In addition, if the air recovered by the return duct 13 is high-temperature air A3 that has been returned via the shelves 10 from zones 4 where the hot air A1 is supplied, the air is recovered to the hot air generator 14 above, while if the returned air is low-temperature air A4 that has been returned via the shelves 10 from zones 4 where the cold air A2 is supplied, the air is recovered to the cold air generator 15 below. For zones where a mixture of the hot air A1 and the cold air A2 is supplied, as a basic principle, if the temperature of a zone is higher than room temperature, the air is returned upward, and if the temperature of a zone is lower than room temperature, the air is returned downward, while air returned from zones close to room temperature may be circulated in either direction depending on factors such as the amount of air flow in the return duct 13 and pressure loss.

That is, in the return duct 13, the temperature of the air A4 returned from the chilled zones 4 is low, so that the specific gravity is high and the air is susceptible to falling, thereby producing a downdraft and being guided to the cold air generator 15 disposed at the bottom. On the other hand, the temperature of the air A3 returned from the heated zones 4 is high, so that the specific gravity is low and the air is susceptible to rising, thereby producing an updraft and being guided to the hot air generator 14 disposed at the top. In addition, as shown in FIG. 1, when both heated regions and chilled regions are provided inside the storage space 3, the heated regions are formed at the top side of the storage space 3 and the chilled regions are formed at the bottom side so that the temperatures of the drafts in the storage space 3 will not be mixed up. Accordingly, the air returned in the return duct 13 is divided above and below and is recovered to the generators 14 and 15 without the high-temperature discharged air A3 and the low-temperature discharged air A4 being mixed. The discharged air A3 and A4 can be recovered without air from a plurality of different temperature regions being mixed in the shared return duct 13 and the hot air A1 and/or cold air A2 of the desired conditions can be recycled and supplied by the hot air generator 14 and the cold air generator 15.

Accordingly, using three ducts, it is possible to provide a duct system DS1 that supplies the hot air A1 and the cold air A2 respectively and also recovers the high-temperature discharged air and the low-temperature discharged air without mixing. Therefore, the duct space 5 for housing the duct system DS1 is reduced and the storage apparatus 1 becomes more compact. In addition, the discharged air can be divided into high-temperature air and low-temperature air and returned to the hot air generator 14 and the cold air generator 15, so that the heat exchanging efficiency in the respective generators is increased, the size of equipment for heating and the equipment for cooling can be reduced, the storage apparatus 1 can therefore be made even smaller and lighter, the manufacturing cost can be reduced, and the running cost can also be reduced.

As described above, conditioning air is blown out from the shelves 10 and is exhausted to the return duct 13 via the shelves 10, but it is also possible to blow out the hot air A1 and the cold air A2 onto products from the supply ducts 11 and 12 and the blown-out air can be recovered via the return duct 13. By blowing out air and returning air via the shelves 10, it is possible to provide the shelves 10 with functions for controlling air flow, distributing the conditioning air, and recovering air, so that the construction of the duct system DS1 can be simplified and a storage apparatus 1 with a simple construction can be provided. Also, by attaching the shelves 10, it is possible to blow out air with appropriate temperature conditions efficiently onto products in units of shelf, so that the storage space 3 can be used extremely flexibly and a variety of products can be stored and displayed in a variety of layouts.

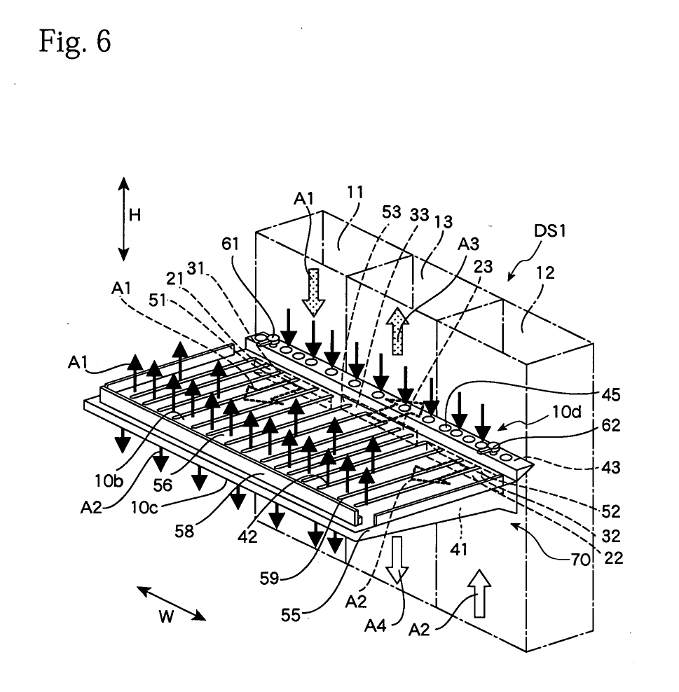

Also, by providing blow openings 42 in the shelf surfaces 10 on which products are disposed and blowing out air upwards, it is possible to reliably form an air flow in the part where the products are disposed, which is effective in keeping products at the desired temperature. The arrangement of the shelves 10 is not limited to the example described above. As shown in FIG. 6, it is also possible to attach a shelf 70 that blows out the hot air A1 from an upper surface 10b and blows out the cold air A2 from a rear surface 10c. When this shelf 70 is used, the high-temperature air A3 in the air space blown out from above the shelf 70 is circulated upward by the return duct 13 and the low-temperature air A4 in the air space blown out from below is circulated downward by the same return duct 13.

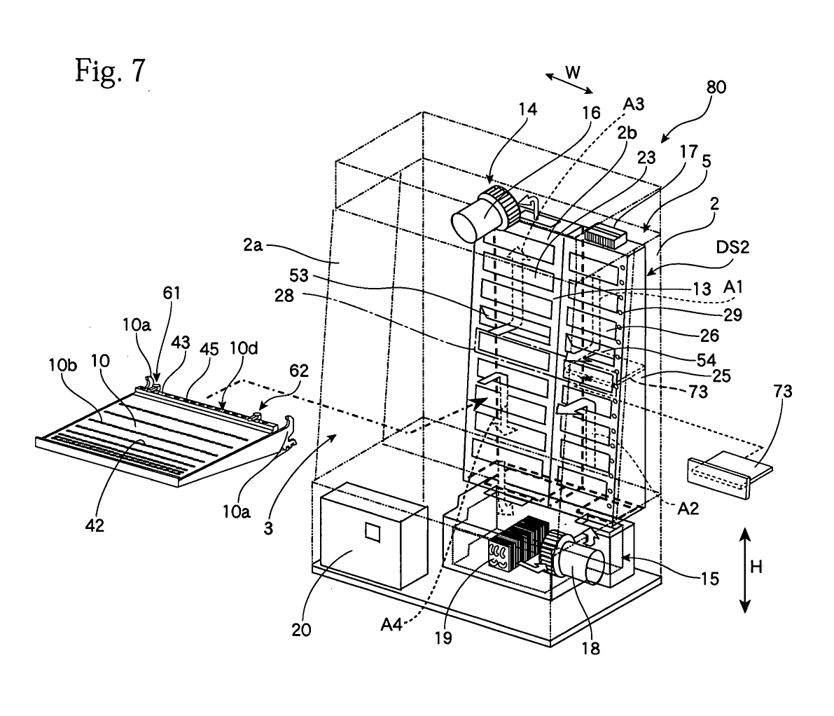

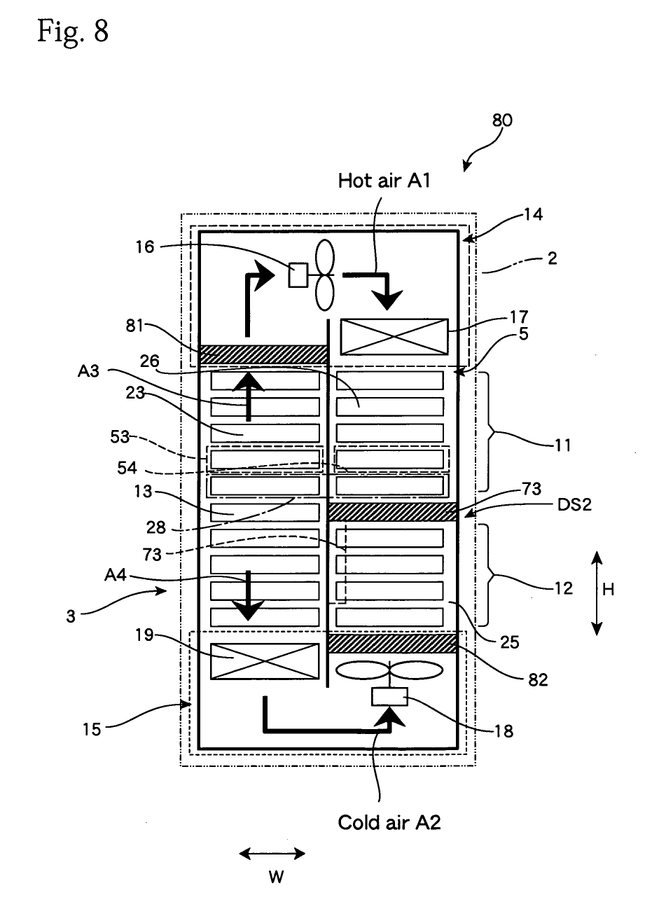

Although the duct system DS1 described above is a system that uses the hot air supply duct 11 and the cold air supply duct 12 that are independent, it is possible to supply the hot air A1 and the cold air A2 using a shared supply duct. FIG. 7 shows a storage apparatus 80 that uses a shared supply duct 25 to supply the hot air A1 and the cold air A2. FIG. 7 corresponds to FIG. 2 and schematically shows a duct system DS2 when seen through the housing 2 in a state where the display shelves 10 have been removed. FIG. 8 shows the duct system DS2 including the shared supply duct 25.

The duct system DS2 utilized in the storage apparatus 80 includes the shared supplied duct 25, which is connected to the upper hot air generator 14 and to the lower cold air generator 15, and a shared return duct 13. The ducts 25 and 13 are respectively provided with a plurality of supply openings 26 and return openings 23 that are aligned in the up-down direction. Dampers 54 and 53 that open and close are provided in the plurality of supply openings 26 and return openings 23, and, in the same way as the duct system DS1 described above, the supply openings 26 and return openings 23 are opened when a shelf 10 is attached.

The shared supply duct 25 can be divided into upper and lower parts by inserting a partition plate 73 from one of supply openings 26, with the upper part of the shared supply duct 25 being used as a duct 11 that supplies the hot air A1 and the lower part being used as a duct 12 that supplies the cold air A2. On the other hand, as described above, the return duct 13 is not divided by a partition plate 73, due to the difference in drafts, the high-temperature air A3 is returned upward and the low-temperature air A4 is returned downward. In this duct system DS2, the storage space 3 can only be divided into a heated region and a chilled region with it not being possible to simultaneously supply the hot air A1 and the cold air A2 to the same display shelf 10, but a supply duct is shared by the hot air A1 and the cold air A2, so that the construction of the duct system can be further simplified and an even more compact storage apparatus 80 can be provided.

In this duct system DS2, A first backflow preventing mechanism 81 that allows only air in the intake direction of the fan 16 of the hot air generator 14 to pass is provided on the sucking side of the fan 16 and a second backflow preventing mechanism 82 that allows only air in the blowing direction of the fan 18 of the cold air generator 15 to pass is provided on the blowing side of the fan 18. Accordingly, when the partition plate 73 is removed and only the hot air generator 14 is driven, in the shared supply duct 25, only the hot air A1 is supplied from above to below until the flow of the hot air A1 is blocked by the second backflow preventing mechanism 82 so that the hot air A1 can be supplied to the entire storage space 3. In the return duct 13, air is returned from the entire storage space 3 without the air being blocked by the first backflow preventing mechanism 81. Accordingly, it is possible to supply only the hot air A1 without the supply duct 25 and the return duct 13 being shorted by the cold air generator 15 so that the storage apparatus 80 can be turned into a dedicated heating showcase.

On the other hand, by driving only the cold air generator 15, only the cold air A2 is supplied from below to above in the shared supply duct 25 until the flow of the cold air A2 is blocked by the first backflow preventing mechanism 81, so that the cold air A2 is supplied to the entire storage space 3. In addition, in the return duct 13, air is recovered from the entire storage space 3 without the air being blocked by the second backflow preventing mechanism 82. Accordingly, it is possible to supply only the cold air A2 without the supply duct 25 and the return duct 13 being shorted by the cold air generator 14 so that the storage apparatus 80 can be turned into a dedicated chilling showcase.

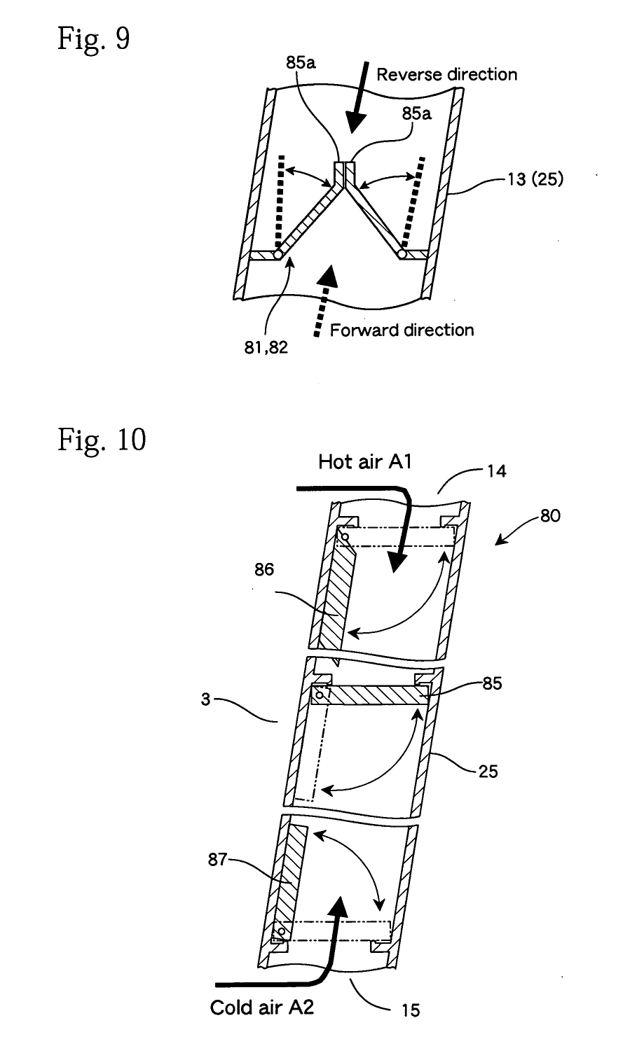

These backflow preventing mechanisms 81 and 82 are not limited to the positions shown in FIG. 8, and these mechanisms 81 and 82 can be attached at any positions, in the hot air generator 14 and the cold air generator 15, where the supply duct 25 and the return duct 13 can be disconnected. One example of the backflow preventing mechanisms 81 and 82 is shown in FIG. 9, with these mechanisms limiting the flow direction by having dampers open and close depending on the direction of air flow inside the duct. The backflow preventing mechanisms 81 and 82 include bendable valve elements 85a that are formed of a light, flexible material such as rubber, and when air flows in the forward direction inside the supply duct 25 or the return duct 13, as shown by the broken lines in FIG. 9, the valve elements 85a are opened by the air flow and the flow of air is not blocked. On the other hand, when air flows in the reverse direction, the valve elements 85a are closed by this flow, thereby blocking the duct.

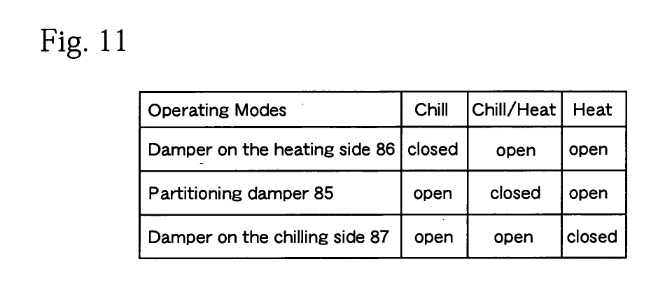

FIG. 10 shows a plurality of dampers, which can close the shared supply duct 25 when operated manually or when an actuator is driven. Instead of the above mechanisms, these dampers can be provided on the inside of the duct 25 in advance. As shown in FIG. 11, when a heated region and a chilled region are formed in the storage space 3, a damper 86 immediately below the hot air generator 14 and a damper 87 immediately above the cold air generator 15 should be opened and a damper 85 at the boundary between the heated region and the chilled region should be closed. When the storage space 3 is used exclusively as a heated region, the damper 87 immediately above the cold air generator 15 should be closed, and the damper 86 immediately below the hot air generator 14 and the damper 85 at the boundary between the heated region and the chilled region should be opened. Also, when the storage space 3 is used exclusively as a chilled region, the damper 86 immediately below the hot air generator 14 should be closed, and the damper 87 immediately above the cold air generator 15 and the damper 85 at the boundary between the heated region and the chilled region should be opened.

Note that although the duct systems DS1 and DS2 according to the present invention have been described above by way of an example of a storage apparatus in the form of a showcase inside which products are displayed, the duct system according to the present invention can be applied to any type of object such as an apparatus, a building, or a system where a hot air generator and a cold air generator are disposed apart with the hot air generator above and the cold air generator below. In particular, the duct system according to the present invention can be favorably applied to showcases since showcases installed in a convenience store, a supermarket, or the like, are subjected to limitations on installation space inside stores so that there is demand for compact showcases in which a heated region and a chilled region can be simultaneously produced. The duct system according to the present invention can also be applied to a variety of showcases, such as showcases where air curtains are formed in individual zones by blowing air out from the front of shelves and/or where air is blown out from the front of shelves toward the rear surface.

In addition, by placing at least one partitioning damper in the return duct 13, physically partitioning can be made in the return duct by opening and closing a damper. It becomes rigid separation in the return air channels for chilling and heating. The partitioning dampers may be switched manually or may be switched automatically by detecting temperature. As one example, if the storage space 3 is divided into two, i.e., a heated region and a chilled region, it is possible to detect the temperature difference in the air recovered above and below the partitioning damper and to carry out controls so that when the temperature difference is above a predetermined value, that partitioning damper can be assumed to be located at the boundary between the heated region and the chilled region and the partitioning damper is closed, while, when the temperature difference in the recovered air is below the predetermined value, it is assumed that the boundary between the heated region and the chilled region is not at the position of this damper and the partitioning damper is opened. By carrying out the same control for all of the partitioning dampers installed inside the return duct 13, it is possible to automatically open and close the partitioning dampers on the return side by simply selecting the air (cold air or hot air) to be blown onto the products.

1. A duct system comprising:
a first duct that guides hot air downward from a hot air generator disposed thereabove and includes a plurality of hot air supply openings at intermediate positions thereof;
a second duct that guides cold air upward from a cold air generator disposed therebelow and includes a plurality of cold air supply openings at intermediate positions thereof; and
a third duct that connects the hot air generator and the cold air generator and includes a plurality of return openings at intermediate positions thereof.

2. A duct system according to claim 1,
comprising a shared supply duct that connects a supply side of the hot air generator and a supply side of the cold air generator,
wherein the first duct and the second duct are produced by dividing the shared supply duct using a partitioning means.

3. A duct system according to claim 2,
wherein the partitioning means is a damper or a partitioning plate.

4. A duct system according to claim 2,
wherein the hot air generator and the cold air generator respectively include backflow preventing mechanisms that block an air flow in a reverse direction.

5. A storage apparatus comprising:
a hot air generator disposed at an upper part of the storage apparatus;
a cold air generator disposed at a lower part of the storage apparatus;
a first duct that guides hot air from the hot air generator downward and includes a plurality of hot air supply openings at intermediate positions thereof;
a second duct that guides cold air from the cold air generator upward and includes a plurality of cold air supply openings at intermediate positions thereof;
a third duct that connects the hot air generator and the cold air generator and includes a plurality of return openings at intermediate positions thereof; and
a housing that constructs a storage space to which at least one of the hot air and the cold air is supplied by at least one of the first duct and the second duct and from which internal air is recovered by the third duct.

6. A storage apparatus according to claim 5,
comprising a shared supply duct that connects a supply side of the hot air generator and a supply side of the cold air generator,
wherein the first duct and the second duct are produced by dividing the shared supply duct using a partitioning means.

7. A storage apparatus comprising:
a hot air generator disposed at an upper part of the storage apparatus;
a cold air generator disposed at a lower part of the storage apparatus;
a first duct that guides hot air from the hot air generator downward and includes a plurality of hot air supply openings at intermediate positions thereof;
a second duct that guides cold air from the cold air generator upward and includes a plurality of cold air supply openings at intermediate positions thereof;
a third duct that connects the hot air generator and the cold air generator and includes a plurality of return openings at intermediate positions thereof; and
a display shelf for displaying products that is connected to at least one of the plurality of hot air supply openings and the plurality of cold air supply openings and includes blow openings that blow out at least one of the hot air and the cold air via the display shelf.

8. A storage apparatus according to claim 7,
wherein the display shelf is connected to one of the plurality of hot air supply openings and one of the plurality of cold air supply openings and blows out air that is a mixture of the hot air and the cold air from the blow openings.

9. A storage apparatus according to claim 7,
wherein the display shelf includes suction holes and is connected to one of the plurality of return openings so that air is discharged via the display shelf.

10. A storage apparatus according to claim 7,
further comprising a housing for constructing a storage space to which at least one of the hot air and the cold air is supplied via the display shelf and from which internal air is recovered via the third duct.
